(19) United States
(12) Patent Application Publication
(10) Pub. No.: US 2025/0165004 A1
(43) Pub. Date: May 22, 2025

(54) METHOD FOR EVALUATING A ROBOT IN SIMULATION

(71) Applicants: INVENTEC (PUDONG) TECHNOLOGY CORPORATION, Shanghai (CN); INVENTEC CORPORATION, Taipei City (TW)

(72) Inventors: Riska Wilian Triany PUTRI, Taipei City (TW); Guilherme Henrique GALELLI CHRISTMANN, Taipei City (TW); Hanjaya MANDALA, Taipei City (TW); Wei-Chao CHEN, Taipei City (TW)

(73) Assignees: INVENTEC (PUDONG) TECHNOLOGY CORPORATION, Shanghai (CN); INVENTEC CORPORATION, Taipei City (TW)

(21) Appl. No.: 18/408,814

(22) Filed: Jan. 10, 2024

(30) Foreign Application Priority Data
Nov. 16, 2023 (CN) 202311535158.4

(51) Int. Cl. G05D 1/622; G06F 30/20

(52) U.S. Cl. CPC G05D 1/622; G06F 30/20

(57) ABSTRACT

A method for evaluating robots in simulation, when executed on a computing device, involves the following steps: obtaining a robot description file created based on the physical properties of a robot, obtaining an environment description file created based on an environment, and obtaining an obstacle description file. A physics simulation engine creates a virtual environment based on the environment description file and obstacle description file. A virtual robot is created based on the robot description file. When the virtual robot navigates from the starting area to the ending area within the virtual environment based on navigation information, the physics simulation engine outputs simulation information. The robot navigation program generates and sends navigation information to the physics simulation engine based on the simulation information. When the virtual robot reaches the ending area, the physics simulation engine outputs evaluation information.

### CROSS-REFERENCE TO RELATED APPLICATIONS

This non-provisional application claims priority under 35 U.S.C. § 119 (a) on Patent Application No(s). 202311535158.4 filed in China on Nov. 16, 2023, the entire contents of which are hereby incorporated by reference.

### BACKGROUND

### 1. Technical Field

The present disclosure relates to digital twin and robot navigation, particularly to a method for evaluating robots in simulation.

### 2. Related Art

The market for commercially available mobile robots is rapidly growing. For example, robot vacuum cleaners are becoming increasingly popular. With so many different brands and models available, it is difficult to determine which robot is the best fit for your needs.

Comparing different robots is a challenging task. One way to do it is to test them physically in a controlled environment. This involves purchasing the robots to compare and letting them perform the same tasks. The robot performances were measured and analyzed to determine the best robot. However, this method can be time-consuming, expensive, and risky. There is a risk of damaging the robots during testing, and if something goes wrong, the entire process must be repeated.

Physical experiments with autonomous robots can be expensive and unpredictable because sensors can malfunction, causing the robot to make mistakes; robots can collide with objects or each other, damaging themselves or the new environment; and testing with different robots requires purchasing new robots, which can be expensive.

### SUMMARY

In light of the above descriptions, the present disclosure provides a method for evaluating robots in simulation. The method can identify the best robot for a real-world environment. It flexibly adjusts its settings to account for different robots and environments.

According to one or more embodiment of the present disclosure, a method for evaluating a robot in simulation is provided. The method is performed by a computing device and includes following steps: creating a robot description file according to a physical property of the robot; creating an environment description file according to an environment; obtaining an obstacle description file configured to define a starting area, an ending area, and a plurality of obstacles; creating a virtual environment according to the environment description file and the obstacle description file, creating a virtual robot according to the robot description file, and outputting simulation information of the virtual robot in the virtual environment by a physics simulation engine; generating and sending navigation information to the physics simulation engine according to the simulation information by a robot navigation procedure; and outputting evaluation information by the physics simulation engine when the virtual robot reaches the ending area.

According to one or more embodiment of the present disclosure, a non-transitory computer-readable recording medium storing a program is provided, and a computing device loads the program and performs following steps: obtaining a robot description file created according to a physical property of a robot; obtaining an environment description file created according to an environment; obtaining an obstacle description file configured to define a starting area, an ending area, and a plurality of obstacles; creating a virtual environment according to the environment description file and the obstacle description file, creating a virtual robot according to the robot description file, and outputting simulation information of the virtual robot in the virtual environment by a physics simulation engine; generating and sending navigation information to the physics simulation engine according to the simulation information by a robot navigation procedure; and outputting evaluation information by the physics simulation engine when the virtual robot reaches the ending area.

In summary, the method for evaluating the robot in simulation proposed by the present disclosure can identify the best robot for a specific task, identify the best environment for a specific robot. The proposed method is implemented as a digital twin simulation to achieve the following benefits: increased efficiency and productivity, reduced costs, improved safety, better decision-making, guarantee performance in the real world.

### BRIEF DESCRIPTION OF THE DRAWINGS

The present disclosure will become more fully understood from the detailed description given hereinbelow and the accompanying drawings which are given by way of illustration only and thus are not limitative of the present disclosure and wherein:

FIG. 1 is a flowchart illustrating a method for evaluating a robot in simulation according to an embodiment of the present disclosure;

FIG. 2 is a design diagram of the robot adopted in an embodiment of the present disclosure;

FIG. 3 is a design diagram of the LiDAR of the robot adopted in an embodiment of the present disclosure;

FIGS. 4 to 7 are schematic diagrams of all predefined obstacles adopted in an embodiment of the present disclosure;

FIG. 8 is a schematic diagram of the virtual environment adopted in an embodiment of the present disclosure;

FIG. 9 is a visualization result of the robot description file in the verification program according to an embodiment of the present disclosure;

FIG. 10 is a result of the virtual robot presented in the physics simulation engine according to an embodiment of the present disclosure;

FIG. 11 is an architecture diagram of the physics simulation engine and robot navigation procedure according to an embodiment of the present disclosure; and

FIG. 12 is an example of an action diagram according to an embodiment of the present disclosure.

### DETAILED DESCRIPTION

In the following detailed description, for purposes of explanation, numerous specific details are set forth in order to provide a thorough understanding of the disclosed embodiments. According to the description, claims and the drawings disclosed in the specification, one skilled in the art may easily understand the concepts and features of the present invention. The following embodiments further illustrate various aspects of the present invention, but are not meant to limit the scope of the present invention.

Simulation is an efficient way to compare robots. It allows for a safe and quick way to test different types of robots in a variety of environments without having to purchase or damage any physical robots. Digital twins create realistic simulations of the real-world to ensure that the robot's performance in the simulation is similar to its performance in the real-world.

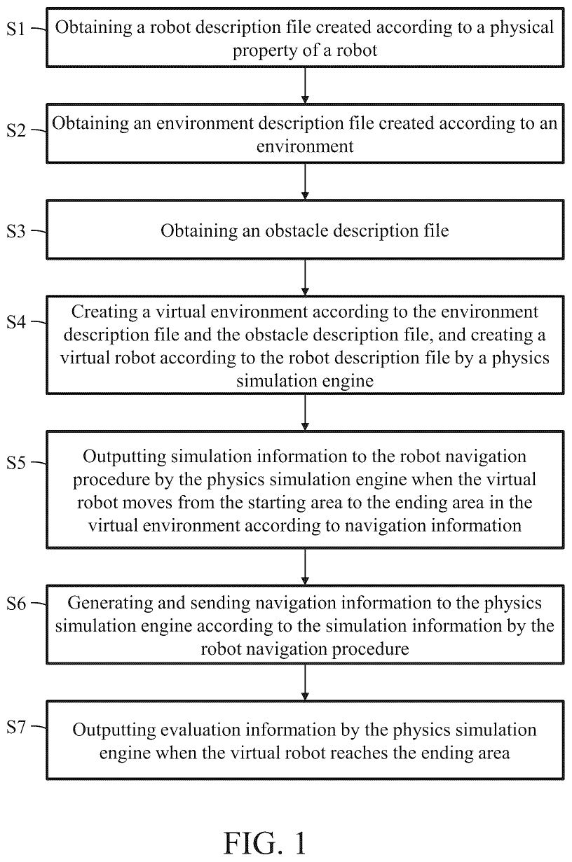

FIG. 1 is a flowchart illustrating a method for evaluating a robot in simulation according to an embodiment of the present disclosure. The method involves loading and executing a program stored in a non-transitory computer-readable recording medium by a computing device to achieve a plurality of operations, as illustrated in steps S1 to S6 in FIG. 1.

In an embodiment, the computing device may adopt at least one of the following examples: Central Processing Unit (CPU), Graphic Processing Unit (GPU), Microcontroller (MCU), Application Processor (AP), Field Programmable Gate Array (FPGA), Application-Specific Integrated Circuit (ASIC), Digital Signal Processor (DSP), System-on-a-Chip (SOC), Deep Learning Accelerator. However, the present disclosure is not limited to these examples.

Step S1, obtaining a robot description file created according to a physical property of a robot. In an embodiment, the robot description file is unified robot description format (URDF), and the physical property includes a plurality of placement positions of multiple joints and an Optical Light Detection And Ranging (LiDAR), and the steps further include: executing a verification procedure according to the robot description file to confirm a plurality of directions of the plurality of joints.

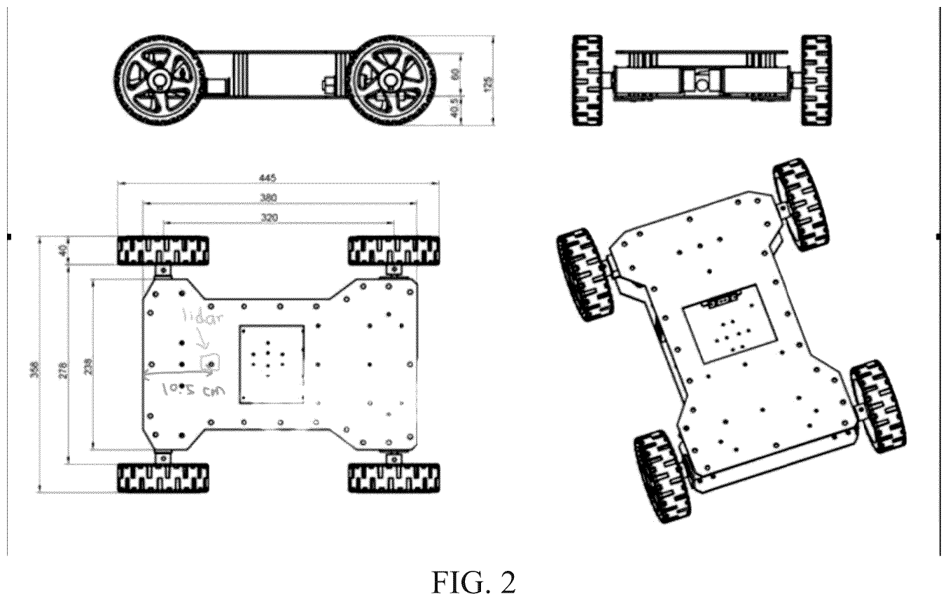

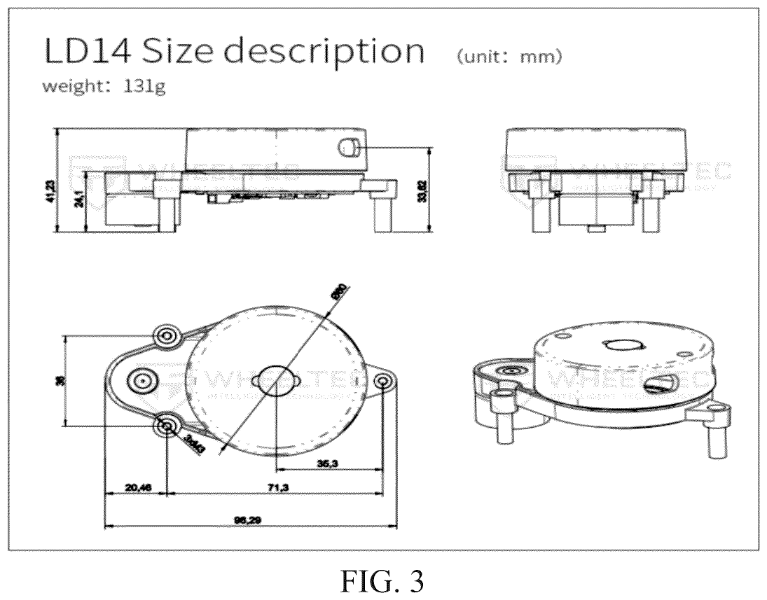

Specifically, every robot has a blueprint that can be converted into a URDF file, a digital description of its physical properties. The URDF files can be put into physics-based simulation platform as a 3D model retaining all the robot's physics properties, which become the digital twin of the robot. Please refer to FIG. 2 and FIG. 3. FIG. 2 is a design diagram of the robot adopted in an embodiment of the present disclosure. FIG. 3 is a design diagram of the LiDAR of the robot adopted in an embodiment of the present disclosure. In an embodiment, the robot adopts a Wheeltec Ackermann robot with Wheeltec LD14 LiDAR that lacked a URDF file. Therefore, it is necessary to create a URDF file for this robot, including the joint positions, physical properties, and measurement data of the robot. To ensure the accuracy of the URDF file, in one embodiment, the present disclosure uses the RVIZ visualization tool in ROS2 as a verification program to confirm the orientation of the robot's joints.

Step S2, obtaining an environment description file created according to an environment. The environment description file includes a three-dimensional mesh and a three-dimensional object. Step S2 includes following sub-steps: creating the three-dimensional mesh of the environment description file by a technique of photogrammetry or structure-from-motion; and creating the three-dimensional object of the environment description file by a three-dimensional modeling software.

Specifically, a digital twin of an environment is a virtual copy of the real world. It can be created by scanning the real-world environment. If the scan does not cover the entire environment, the missing parts can be created by hand using a three-dimensional modeling software. In one embodiment, the three-dimensional modeling software is Blender, which can be utilized to edit three-dimensional objects and export FBX files containing three-dimensional objects, materials, and lighting.

Step S3, obtaining an obstacle description file. The obstacle description file is configured to define a starting area, an ending area, and a plurality of obstacles.

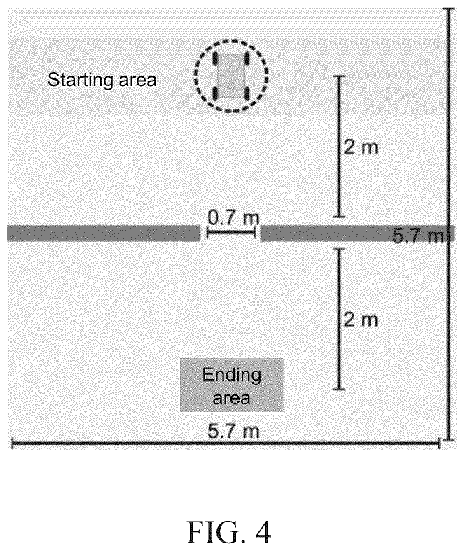

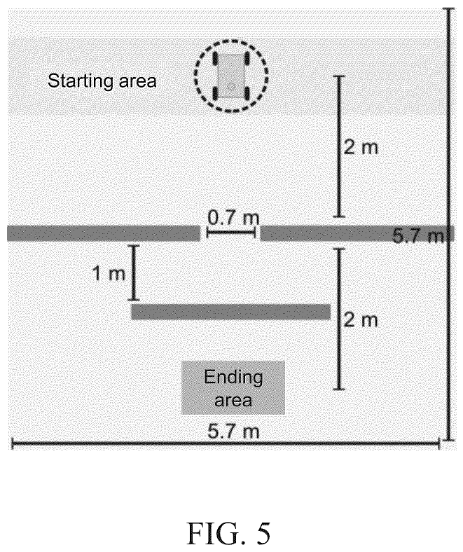

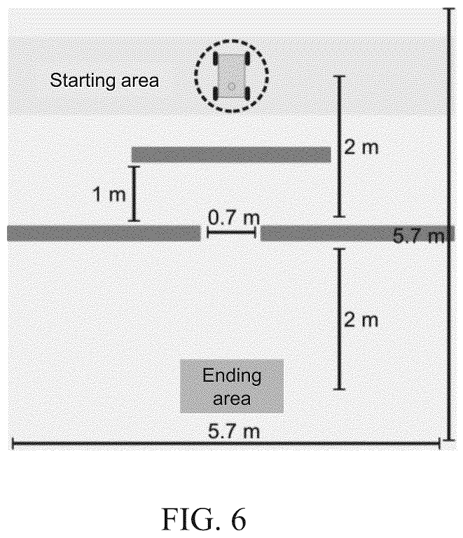

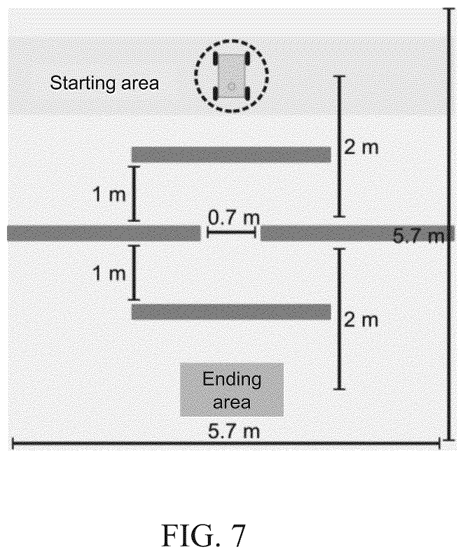

In an embodiment, the configuration of obstacles, start area, and goal area is defined in a YAML file. Obstacles can be divided into two types. The first type is predefined obstacles. Please refer to FIG. 4 to FIG. 7, which are schematic diagrams of all predefined obstacles adopted in an embodiment of the present disclosure. The second type is random obstacles, and their generation mechanism is based on the following reference: Daniel Perille et al. “Benchmarking Metric Ground Navigation.” In: CoRR abs/2008.13315 (2020). The table 1 below shows several parameters that need to be configured in the YAML file. FIG. 4 shows the distribution of generated random obstacles. In FIG. 4, the value 0 indicates empty space, and the value 1 indicates an obstacle.

TABLE 1
These are parameters to generate random obstacles. Different
obstacles are generated from different parameter values.

| Parameters | Descriptions | Values |
|---|---|---|
| Rows | The number of rows | 57 |
| Cols | The number of columns | 30 |
| fill_pct | The percentage of the obstacles | 0.2 |
| | occupied by the whole grid | |
| seed | The seed for the random generator | 1 |
| smooth_iter | The number of iterations to smooth | 5 |
| | the generated obstacles | |

In an embodiment, to incorporate random obstacles into the simulation, a grid-based system is implemented, where each grid corresponds to 0.1 meters in the real world. Cubes are created to represent obstacles, replacing the portions with a value of 1 in FIG. 4. The positions of these cubes are determined by calculating the grid number. To ensure that the cubes are accurately positioned at the center of the grid, the positions of the cubes are further adjusted based on the scale of the cubes, as following Equation 1:

Cube position=(original grid−half grid)/10+half cube's scale (Equation 1)

Step S4, creating a virtual environment according to the environment description file and the obstacle description file, and creating a virtual robot according to the robot description file by a physics simulation engine.

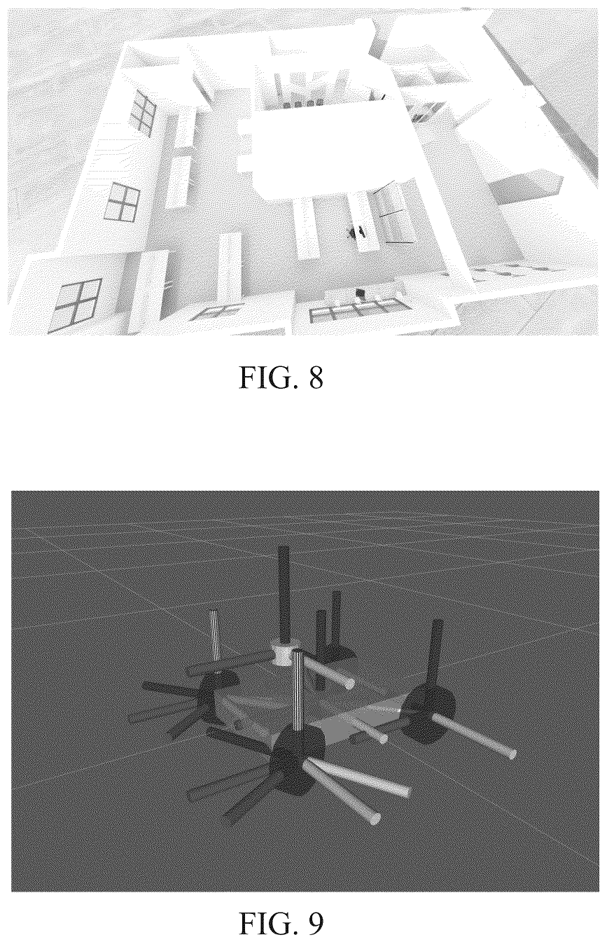

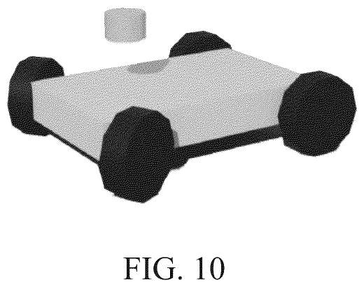

Please refer to FIG. 8, FIG. 9, and FIG. 10. FIG. 8 is a schematic diagram of the virtual environment adopted in an embodiment of the present disclosure. FIG. 9 is a visualization result of the robot description file in the verification program according to an embodiment of the present disclosure. FIG. 10 is a result of the virtual robot presented in the physics simulation engine according to an embodiment of the present disclosure.

In an embodiment, the physics simulation engine is NVIDIA Omniverse™ Isaac Sim. The choice of Isaac Sim is driven by its advanced Ray Tracing technologies, enabling the simulation to render scenes that closely resemble real world lighting conditions. In step S4, the URDF file of the robot is imported into Isaac Sim to create a simulated version of the robot. Additionally, the FBX file containing three-dimensional objects, materials, and lighting is imported into Isaac Sim. To make the digital twin as realistic as possible, adjustments to the simulation's lighting and physical properties are necessary. Moreover, since the imported FBX file may be incompatible with the file format used by Isaac Sim (Universal Scene Description, USD), repairs are needed, and the environment is saved as a USD file.

The present disclosure develops an application through Isaac Sim to operate the virtual environment and the virtual robot within it. The virtual environment has a top-down view camera facing towards the center of the scenario location. This camera is set as the main camera of the application. The configuration of the USD file location and scenario camera are saved as a YAML file.

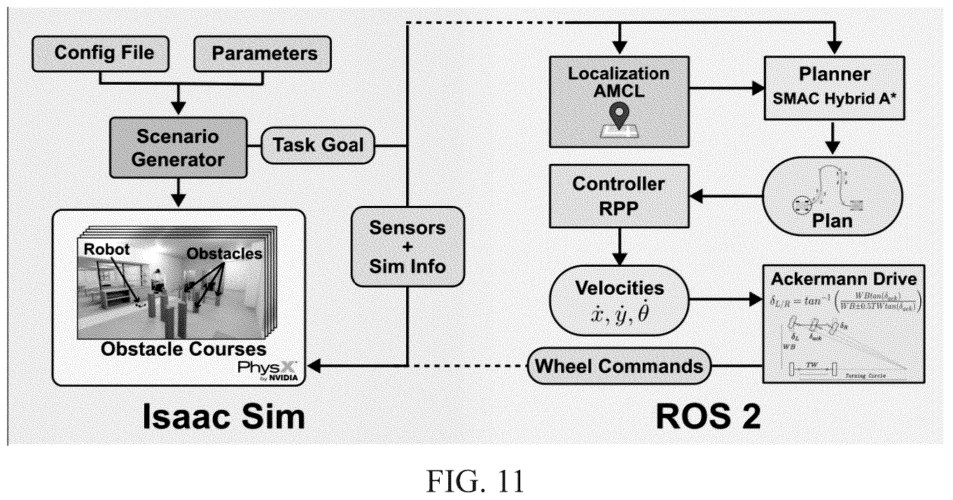

Step S5, as the virtual robot moves from the starting area to the ending area in the virtual environment according to navigation information, the physics simulation engine outputs simulation information to the robot navigation procedure. In Step S6, the robot navigation procedure generates and sends navigation information to the physics simulation engine according to the simulation information. In an embodiment, the robot navigation procedure is Robot Operating System 2 navigation stack (ROS2 navigation stack). FIG. 11 is an architecture diagram of the physics simulation engine and robot navigation procedure according to an embodiment of the present disclosure. As shown in FIG. 11, the physics simulation engine, Issac Sim, generates the scenario and provides simulation information as well as sensor data to the robot navigation procedure ROS2. The latter then performs path planning and controls the robot to reach the ending area.

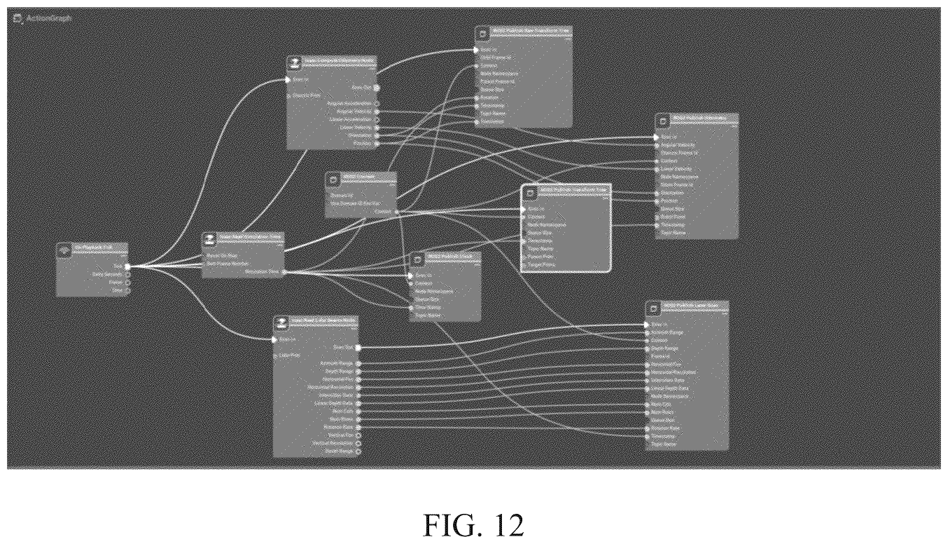

To navigate the robot towards the goal position, it is necessary to establish a connection between Isaac Sim simulation and ROS2. This is achieved through the Isaac Sim ROS Bridge extension and the Humble version of ROS2. The simulation information includes the robot's pose, LiDAR data, and simulation time. In an embodiment, the simulation information is transmitted from Isaac Sim to the ROS2 navigation stack using an action graph created from a Python script. FIG. 12 provides an example of the action graph. Additionally, a custom node subscriber is implemented to receive virtual robot velocity command, together with the left and right steering angles that control the movement of the robot wheels.

Next, the ROS2 navigation parameters used in the robot navigation procedure are explained here. The navigation performances of the virtual robot rely on the configuring and fine-tuning various parameters, which are stored in a YAML file. These parameters include: localization, Behavior Tree (BT) navigator, control server, local costmap, global costmap, map server, planning server, behavior server, and velocity smoother. In an embodiment, the planner adopts SMAC Hybrid A*. The controller adopts the Regulated Pure Pursuit (RPP) controller, both optimized for Ackermann robots. The localization technique employed is Adaptive Monte Carlo Localization (AMCL). Table 2 below presents the fine-tuned results of ROS2 navigation parameters.

TABLE 2
The adjusted parameter of ROS2 navigation parameters.

| Server | Parameters | Value |
|---|---|---|
| AMCL | alphal to alpha5 | 0.05 |
| | base_frame_id | base_link |
| | laser_max_range | 25.0 |
| | laser_min_range | 0.1 |
| | robot_model_type | nav2_amcl:: |
| | | DifferentialMotionModel |
| | always_reset_initial_pose | true |
| Bt_navigator | transform_tolerance | 0.2 |
| | bt_loop_duration | 20 |
| | default_server_timeout | 40 |
| Controller_server | controller_frequency | controller_frequency 60.0 |
| | min_y_velocity_threshold | min_y_velocity_threshold |
| | | 0.001 |
| | progress_checker.required_movement_radius | 0.1 |
| | general_goal_checker.xy_goal_tolerance | 0.05 |
| Controller_server | plugin | “nav2_regulated_{—} |
| Follow Path | | pure_pursuit_controller:: |
| | | RegulatedPurePursuitController” |
| | transform_tolerance | 1.0 |
| | use_velocity_scaled_lookahead_dist | true |
| | lookahead_dist | 0.6 |
| | min_lookahead_dist | 0.1 |
| | max_lookahead_dist | 0.9 |
| | lookahead_time | 6.0 |
| | approach_velocity_scaling_dist | 0.25 |
| | curvature_lookahead_dist | 0.15 |
| | regulated_linear_scaling_min_radius | 1.0 |
| | use_rotate_to_heading | false |
| | allow_reversing | true |
| | use_interpolation | false |
| | inflation_cost_scaling_dist | 7.0 |
| | cost_scaling_dist | 4.0 |
| | cost_scaling_gain | 1.0 |
| Local | update_frequency | update_frequency 60.0 |
| costmap | publish_frequency | publish_frequency 60.0 |
| | transform_tolerance | transform_tolerance 1.0 |
| | static_map | static_map false |
| | rolling_window | rolling_window true |
| | width | width 6 |
| | height | height 6 |
| | footprint | “[[0.225, 0.179], [0.225, |
| | | −0.179], [−0.225, −0.179], |
| | | [−0.225, 0.179]]” |
| | footprint_padding | −0.129 |
| | lethal_cost_threshold | 100 |
| | plugin_names | [“obstacle_layer”, |
| | | “inflation_layer”] |
| | inflation_layer.cost_scaling_factor | 7.0 |
| | inflation_layer.inflation_radius | 4.0 |
| Global_cost | update_frequency | 10.0 |
| map | publish_frequency | 10.0 |
| | transform_tolerance | 1.0 |
| | footprint | “[[0.225, 0.179], [0.225, |
| | | −0.179], [−0.225, −0.179], |
| | | [−0.225, 0.179]]” |
| | footprint_padding | 0.01 |
| | lethal_cost_threshold | 100 |
| | width | 16 |
| | height | 16 |
| | origin_x | −8.0 |
| | origin_y | −8.0 |
| | use_max | true |
| | static_map | true |
| | plugins | [“static_layer”, |
| | | “obstacle_layer”, |
| | | “inflation_layer”] |
| | cost_scaling_factor | 7.0 |
| | inflation_radius | 4.0 |
| Planner_server | plugin | “nav2_smac_planner/ |
| GridBased | | SmacPlannerHybrid” |
| | Tolerance | 0.1 |
| | max_planning_time | 5000.0 |
| | motion_model_for_search | “REEDS_SHEPP” |
| | analytic_expansion_ratio | 1.3 |
| | minimum_turning_radius | 0.3 |
| | reverse_penalty | 1.0 |
| | change_penalty | 0.2 |
| | non_straight_penalty | 1.05 |
| | cost_penalty | 1.3 |
| | cache_obstacle_heuristic | true |
| | smooth_path | false |
| Behavior_server | behavior_plugins | [“spin”, “backup”, |
| | | “drive_on_heading”, |
| | | “wait”] |
| | transform_tolerance | 1.0 |
| | smoothing_frequency | 60.0 |
| Velocity_smoother | max_velocity | [0.5, 0.0, 1.0] |
| | min_velocity | [−0.5, 0.0, −1.0] |

The navigation performance of the robot is significantly influenced by the values of the inflation_radius and cost_scaling_factor in the costmap, considering the relatively tight space for the robot to maneuver. Different combinations of these values result in varying paths being formed. For optimal performance, it is necessary to ensure that the path formed lies in the middle of the two obstacles, as the RPP controller strictly follows the given path. Additionally, a footprint_padding value of −0.129 was utilized in the local costmap to reduce the robot's tolerance for proximity to obstacles, preventing navigation from being halted prematurely. If a specific parameter is not mentioned, it indicates that the default value is used. Additionally, the use_sim_time parameter was consistently set to true.

In an embodiment, the occupancy map and its configuration were generated using Isaac Sim and then utilized by the ROS2 navigation map server to aid in localizing the robot pose. The occupancy map does not contain any obstacles.

In an embodiment, the controller server generates a velocity command comprising both linear and angular velocities. The angular velocities are further processed using the Ackermann equation (as Equation 2 below) to determine the corresponding left and right angular velocities. The linear velocity, as well as the calculated left and right angular velocities, are transmitted back to the Isaac Sim simulation to drive the movement of the robot's wheels, allowing the robot to navigate and move effectively.

$${δ}_{L / R} = {tan}^{- 1} ( \frac{WB tan ( {δ}_{Ack} )}{WB \pm 0.5 TW tan ( {δ}_{Ack} )} ) \qquad ( Equation 2 )$$

In an embodiment, the ROS2 launcher is implemented with a Python script, which includes: setting the use_sim_time parameter to true, configuring the navigation parameter locations, map configuration location, Nav2 bringup launcher, RVIZ node, Static transform node from map to odom, and Ackermann node.

Step S7, outputting evaluation information by the physics simulation engine when the virtual robot reaches the ending area.

In an embodiment, an experiment is conducted by running two separate terminals. In the first terminal, a standalone application of Isaac Sim is executed. In the second terminal, the ROS2 launch file is executed to trigger the appearance of the RVIZ window. This window displays the previously mentioned occupancy map. It is crucial to run both terminals simultaneously because the timer for each round in the Isaac Sim simulation continues to run even if the robot remains stationary. To accommodate this, the initial round (round 0) is allowed to continue running until it reaches the timeout duration to allow sufficient time for launching the ROS2 Navigation Stack. It is worth noting that the robot's localization may not be accurate during the initial launch of the ROS2 Navigation Stack. However, starting from round 1, the robot can be localized properly, marking the official beginning of the test.

In an embodiment, the present disclosure utilizes the environment presented in FIG. 8 and FIG. 13, conducting 100 rounds of experiments with four default scenarios and two random scenarios. After the virtual robot reached the goal or encountered an obstacle, it proceeded to the next round, with the virtual robot starting again from the initial positions. The evaluation information outputted in each round includes:
start_position: the randomized position of the robot at the beginning of each round.
arrived: indicates whether the robot successfully reached the goal.
hit: indicates whether the robot collided with any obstacles.
time_spend: the duration of each round.
end_position: The final position of the robot before proceeding to the next round.
goal_position: The position of the target goal in each round.
environment: The specific environment configuration used for each round.
scenario: The scenario configuration used for each round.
robot: The specific robot model used for each round.
goal_tolerance_m: The maximum allowed Euclidean distance in meters between the robot and the goal position for it to be considered reached.

The above evaluation information is stored in a CSV file. In an embodiment, the evaluation information is further processed and converted into percentages for analysis. The timeout rate indicates instances where the virtual robot either got stuck or took long time to reach the goal (exceeding the maximum time allotted for each round). The average time refers to the average duration spent by only those robots that arrive at the goal location. The summarized results are presented in Table 3 below.

TABLE 3
The results of the navigation evaluation from 6 sample scenarios.

| Scenario | Goal Rate | Hit Rate | Timeout Rate | Average Time |
|---|---|---|---|---|
| 1 | 98% | 0% | 2% | 47.10 s |
| 2 | 91% | 4% | 5% | 89.42 s |
| 3 | 92% | 4% | 4% | 66.81 s |
| 4 | 87% | 3% | 10% | 104.52 s |
| Random Easy | 98% | 1% | 1% | 57.31 s |
| Random Hard | 88% | 7% | 5% | 70.83 s |

The table 3 shows a goal rate of 98% for Scenario 1 and Scenario Random Easy. However, Scenario 1 has a lower average time spent compared to Scenario Random Easy. This difference can be attributed to the fact that the path in Scenario 1 is much simpler than in Scenario Random Easy. Scenarios 2 and 3 showed similar performance, but the robot in Scenario 2 took approximately 23 seconds longer on average than in Scenario 3. In Scenario 2, the robot had to go straight initially and sometimes needed extra time to orient itself in tight gaps before turning around. However, in Scenario 3, the robot encountered obstacles that forced it to make a turn before proceeding straight, eliminating the need for additional orientation time. As a result, the robot in Scenario 3 navigated faster and reached the goal more quickly. Scenario 4 and the random hard scenario exhibit similar performance but with a more complex arrangement of obstacles. The random hard scenario, in particular, has a higher hit rate and lower average time spent due to the presence of scattered obstacles.

The RPP Controller used in this experiment slows down the robot when there are curvature paths or obstacles, especially in scenarios 2, 3, and 4, where sharp turns and surrounding obstacles are present. This approach aims to prevent collisions and ensure the robot's safe arrival at the goal, even if it slower. If the robot gets too close to obstacles, it stops and attempts to generate a new path. Since an Ackermann robot requires space to turn around, there are instances where a seemingly passable path visually may not be feasible for the robot to navigate due to insufficient turning clearance. Consequently, the robot remains stationary until it exceeds the time limit, resulting in a higher timeout rate.

In view of the above, the present disclosure provides a method for evaluating a robot in simulation and a non-transitory computer-readable recording medium, which offer a cost-effective approach to generates a wide range of customized test environments. The recorded values provide extensive data for analysis. Using Digital Twin guarantees that the test results closely resemble real-world scenarios. Optimizing the robot's navigation performance requires configuring and fine-tuning specific components tailored to the robot's type.

What is claimed is:

1. A method for evaluating a robot in simulation, performed by a computing device, comprising:
creating a robot description file according to a physical property of the robot;
creating an environment description file according to an environment;
obtaining an obstacle description file configured to define a starting area, an ending area, and a plurality of obstacles;
creating a virtual environment according to the environment description file and the obstacle description file, creating a virtual robot according to the robot description file, and outputting simulation information of the virtual robot in the virtual environment by a physics simulation engine;
generating and sending navigation information to the physics simulation engine according to the simulation information by a robot navigation procedure; and
outputting evaluation information by the physics simulation engine when the virtual robot reaches the ending area.

2. The method for evaluating the robot in simulation of claim 1, wherein the robot description file is in unified robot description format (URDF), the physical property includes a plurality of placement positions of multiple joints and an Optical Light Detection And Ranging (LiDAR), and the method further includes: executing a verification procedure according to the robot description file to confirm a plurality of directions of the plurality of joints.

3. The method for evaluating the robot in simulation of claim 1, wherein the environment description file includes a three-dimensional mesh and a three-dimensional object, and creating the environment description file according to the environment includes:
creating the three-dimensional mesh of the environment description file by a technique of photogrammetry or structure-from-motion; and
creating the three-dimensional object of the environment description file by a three-dimensional modeling software.

4. A non-transitory computer-readable recording medium storing a program, wherein a computing device loads the program and performs following steps:
obtaining a robot description file created according to a physical property of a robot;
obtaining an environment description file created according to an environment;
obtaining an obstacle description file configured to define a starting area, an ending area, and a plurality of obstacles;
creating a virtual environment according to the environment description file and the obstacle description file, creating a virtual robot according to the robot description file, and outputting simulation information of the virtual robot in the virtual environment by a physics simulation engine;
generating and sending navigation information to the physics simulation engine according to the simulation information by a robot navigation procedure; and
outputting evaluation information by the physics simulation engine when the virtual robot reaches the ending area.

5. The non-transitory computer-readable recording medium of claim 4, wherein the robot description file is in unified robot description format (URDF), the physical property includes a plurality of placement positions of multiple joints and an Optical Light Detection And Ranging (LiDAR), and the steps further include: executing a verification procedure according to the robot description file to confirm a plurality of directions of the plurality of joints.

6. The non-transitory computer-readable recording medium of claim 4, wherein the environment description file includes a three-dimensional mesh and a three-dimensional object, and creating the environment description file according to the environment includes:
creating the three-dimensional mesh of the environment description file by a technique of photogrammetry or structure-from-motion; and
creating the three-dimensional object of the environment description file by a three-dimensional modeling software.
